(19) United States
(12) Patent Application Publication
(10) Pub. No.: US 2008/0094264 A1
(43) Pub. Date: Apr. 24, 2008

(54) Digital-to-Analog Converting Circuit for Power Soft-Switching

(75) Inventor: Yi-Chan Lin, Taipei City (TW)

Correspondence Address: WPAT, PC, 7225 BEVERLY ST., ANNANDALE, VA, 22003, US

(73) Assignee: HOLTEK SEMICONDUCTOR INC., Hsinchu (TW)

(21) Appl. No.: 11/620,038

(22) Filed: Jan. 4, 2007

(30) Foreign Application Priority Data
Oct. 20, 2006 (TW) 095218523

(51) Int. Cl. H03M 1/66

(52) U.S. Cl. 341/144

(57) ABSTRACT

A digital-to-analog converting circuit for power soft-switching, comprising: a metal-oxide-semiconductor field-effect transistor (MOSFET); a digital-to-analog control circuit, for controlling the MOSFET to operate in either the cut-off region, the saturation region or the linear region; a digital control unit, using an output signal so as to control an input current into the MOSFET; and a DC-to-DC inverter, controlled by the MOSFET so as to invert external DC power into a certain level for electronic products.

### BACKGROUND OF THE INVENTION

1. Field of the Invention

The present invention generally relates to a digital-to-analog converting circuit for power soft-switching and, more particularly, to a digital-to-analog converting circuit for controlling a p-channel metal-oxide-semiconductor field-effect transistor (p-MOSFET) so as to turn on the power. The digital-to-analog converting circuit is used to precisely control the turn-on resistance of the p-MOSFET so that the input current is controlled. Moreover, the digital control data of the digital-to-analog converting circuit is adjusted according to the regulating capacitance at the load terminal in order for use in various electronic products.

2. Description of the Prior Art

DC-to-DC inversion for a power supply is for inverting external DC power into a certain level for electronic products. Generally, there are three types of DC-to-DC inverters such as boost, buck and buck-boost that are widely used in portable electronic products requiring high operation efficiency and low stand-by consumption. The three types of DC-to-DC inverters are examples of switching power supplies that exhibit high operation efficiency. During the stand-by operation, part of the power is cut off so as to retain the stand-by operation. Therefore, a p-MOSFET is required as a switch at the front end of the DC-to-DC inverters.

A general DC-to-DC inverter uses a p-MOSFET as a switch. However, the control circuit for the p-MOSFET requires precise design; otherwise, it often occurs that the power for electronic products become unreliable. Please refer to FIG. 1, which shows the input voltage of a DC-to-DC inverter when the p-MOSFET is turned on. Prior to the activation of a DC-to-DC inverter, the p-MOSFET is turned on so that the input current flows into the load terminal transiently. Therefore, there must be a regulating capacitor disposed at the load terminal in order for output voltage regulation so as to prevent the output voltage from rippling. The regulating capacitor is transiently short and a large current is induced by the regulating capacitor. Generally, portable electronic products are powered by batteries, which provide limited currents. The aforementioned large current induced by the regulating capacitor causes the input voltage to drop abruptly so that the circuit is mal-functional.

In order to overcome the aforementioned problem, in the prior art, a plurality of small-current p-MOSFETs are disposed so that the p-MOSFETs are turned on in batches to limit the input current to flow into the load terminal. However, additional problems include:

1) lowered performance of the portable electronic products due to higher turn-on resistance R_{DS} of the p-MOSFETs because the plurality of small-current p-MOSFETs are embedded in the IC;

2) risk in burning down the p-MOSFETs when the input voltage drops abruptly because the p-MOSFETs are turned on in batches and the controlling of time is too long; and

3) turn-on delay due to layout inconsistency of the p-MOSFETs so that the switching of the p-MOSFETs can not be precisely controlled.

Therefore, there exists a need in providing a digital-to-analog converting circuit for power soft-switching so as to overcome the aforementioned problems.

### SUMMARY OF THE INVENTION

It is a primary object of the present invention to provide a digital-to-analog converting circuit for power soft-switching for controlling a p-channel metal-oxide-semiconductor field-effect transistor (p-MOSFET) so as to turn on the power. The digital-to-analog converting circuit is used to precisely control the turn-on resistance of the p-MOSFET so that the input current is controlled. Moreover, the digital control data of the digital-to-analog converting circuit is adjusted according to the regulating capacitance at the load terminal in order for use in various electronic products.

In order to achieve the foregoing object, the present invention provides a digital-to-analog converting circuit for power soft-switching, comprising: a metal-oxide-semiconductor field-effect transistor (MOSFET); a digital-to-analog control circuit, for controlling the MOSFET to operate in either the cut-off region, the saturation region or the linear region; a digital control unit, using an output signal so as to control an input current into the MOSFET; and a DC-to-DC inverter, controlled by the MOSFET so as to invert external DC power into a certain level for electronic products.

### BRIEF DESCRIPTION OF THE DRAWINGS

The objects, spirits and advantages of the preferred embodiment of the present invention will be readily understood by the accompanying drawings and detailed descriptions, wherein:

FIG. 1 shows the input voltage of a DC-to-DC inverter when the p-MOSFET is turned on;

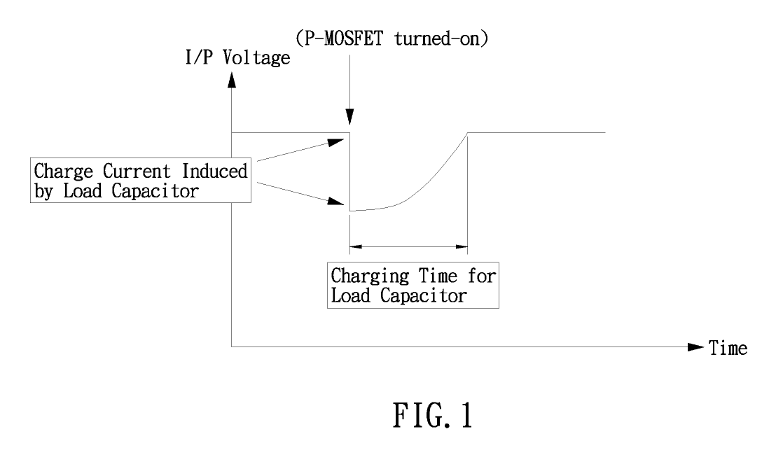

FIG. 2 shows a digital-to-analog converting circuit for controlling a p-MOSFET so as to turn on the power according to the present invention;

FIG. 3 is a detailed circuit diagram of the digital-to-analog control circuit in FIG. 2;

FIG. 4 shows the reduction in R_{DS} of the p-MOSFET caused by an 8-bit data input into the digital-to-analog converting circuit in FIG. 2;

FIG. 5 is schematic block diagram showing a digital-to-analog converting circuit for power soft-switching according to the present invention;

FIG. 6 is a circuit diagram of a boost circuit according to the present invention;

FIG. 7 is a circuit diagram of a buck circuit according to the present invention; and

FIG. 8 is a circuit diagram of a buck-boost circuit according to the present invention.

### DETAILED DESCRIPTION OF THE PREFERRED EMBODIMENT

The present invention providing a digital-to-analog converting circuit for power soft-switching can be exemplified by the preferred embodiment as described hereinafter.

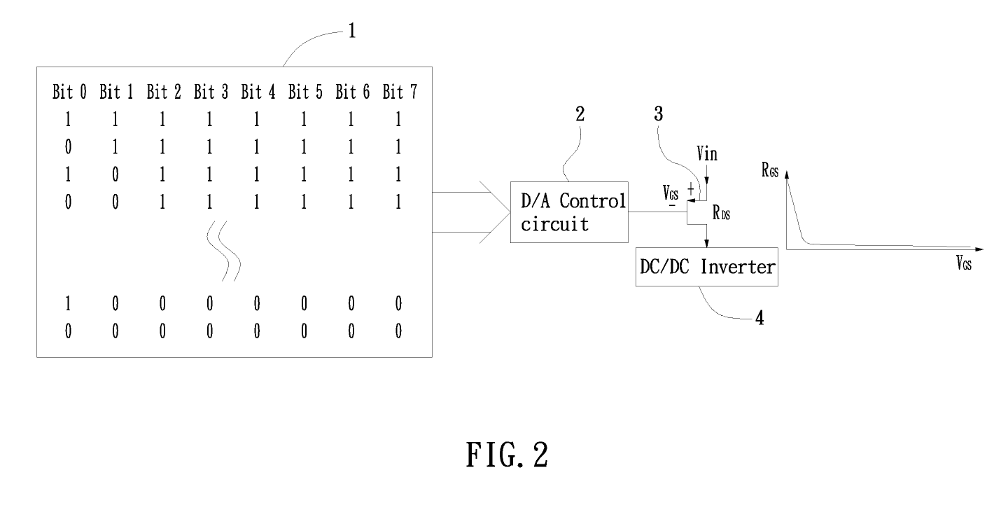

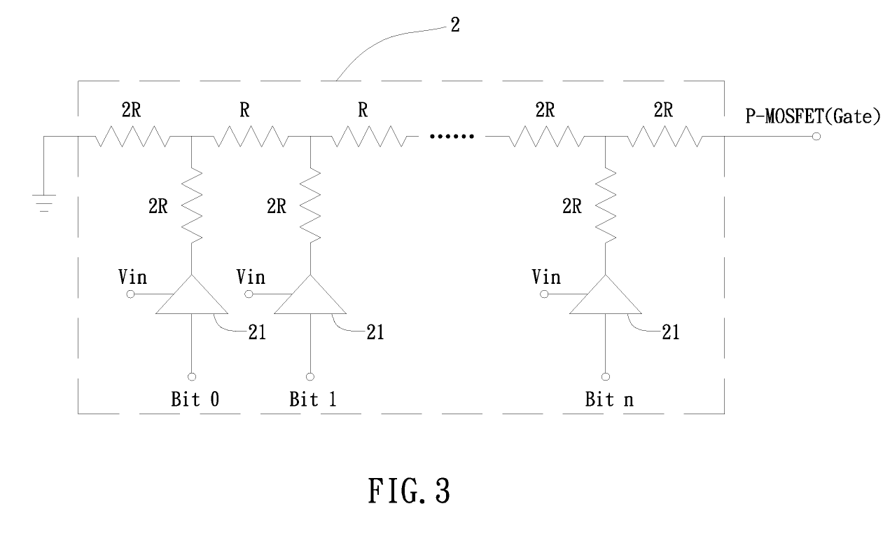

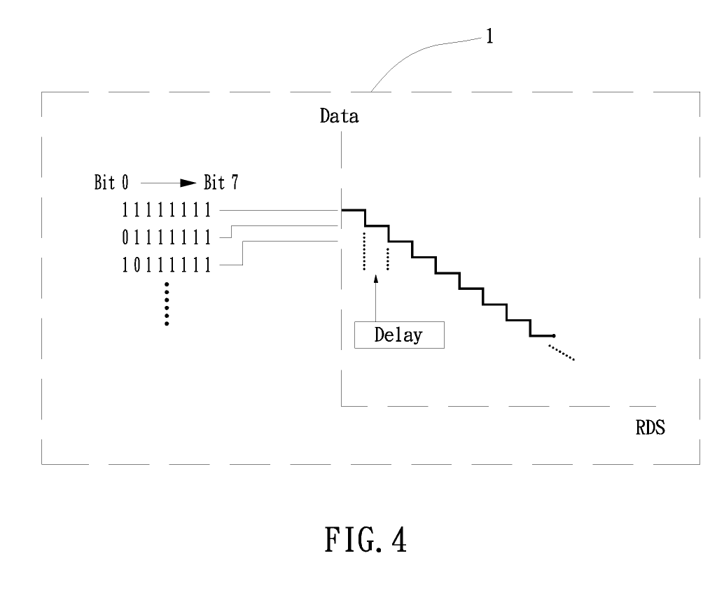

Please refer to FIG. 2, which shows a digital-to-analog converting circuit for controlling a p-MOSFET so as to turn on the power according to the present invention. The digital-to-analog converting circuit comprises a digital control unit 1, a digital-to-analog control circuit 2, a DC-to-DC inverter 4 and a p-MOSFET 3. Please also refer to FIG. 3 and FIG. 4, wherein the digital-to-analog control circuit 2 comprises a plurality of resistors (R's and 2R's) and is controlled by an output signal from the digital control unit 1 so as to control an input current into the p-MOSFET 3. In the present embodiment, the output signal is 8-bit. However, the persons with ordinary skills in art may modify the digital control unit 1 so as to output 16-bit, 32-bit or 64-bit signals within the scope of the present invention. Moreover, a driver 21 is further disposed between the digital-to-analog control circuit 2 and the digital control unit 1 so as to enhance the output signal from the digital control unit 1 to drive the p-MOSFET 3. The digital-to-analog control circuit 2 controls the p-MOSFET 3 to operate in either the cut-off region, the saturation region or the linear region to control the DC-to-DC inverter 4. The DC-to-DC inverter 4 comprises one of a boost circuit, a buck circuit and a buck-boost circuit.

Prior to the activation of an electronic product, the p-MOSFET 3 is turned on to operate in the linear region with the rise in V_{GS}. When V_{GS} rises to reach a threshold value and R_{DS} falls to a certain value, the p-MOSFET 3 enters the saturation region. For the p-MOSFET 3, R_{DS} varies with V_{GS}. If V_{GS} falls below a certain value, R_{DS} follows to drop abruptly. The 8-bit output signal from the digital control unit 1 to the digital-to-analog control circuit 2 provides a delay time so as to precisely control the input current into the p-MOSFET.

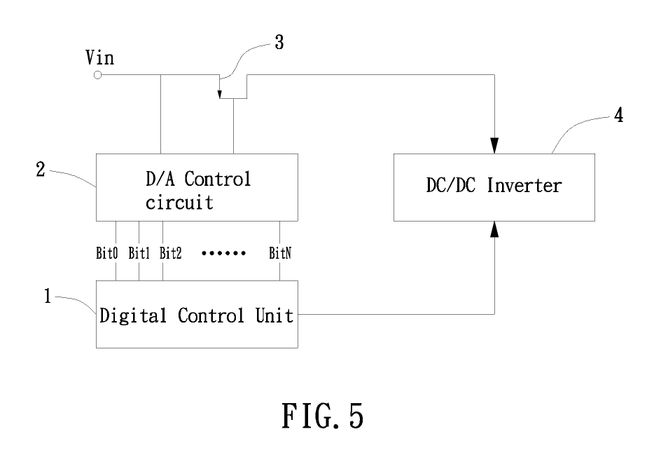

Please refer to FIG. 5, which is schematic block diagram showing a digital-to-analog converting circuit for power soft-switching according to the present invention. The digital-to-analog converting circuit comprises: a p-MOSFET 3; a digital-to-analog control circuit 2, for controlling the p-MOSFET 3 to operate in either the cut-off region, the saturation region or the linear region; a digital control unit 1, using an output signal so as to control an input current into the p-MOSFET 3; and a DC-to-DC inverter 4, controlled by the p-MOSFET 3 so as to invert external DC power into a certain level for electronic products.

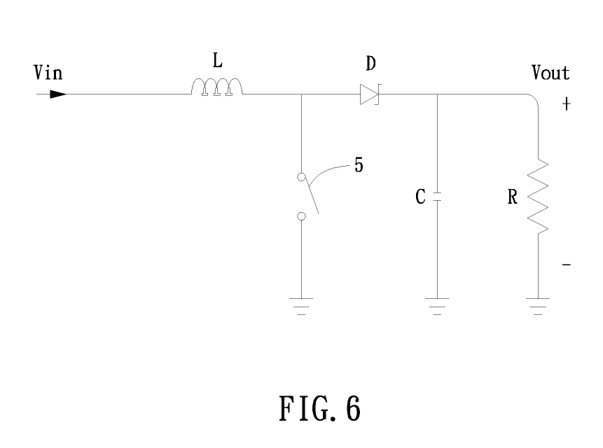

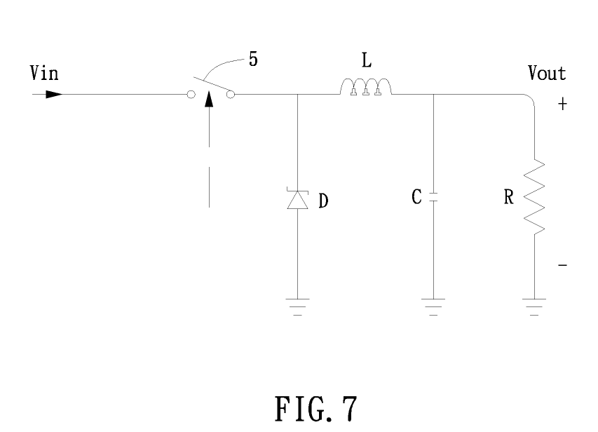

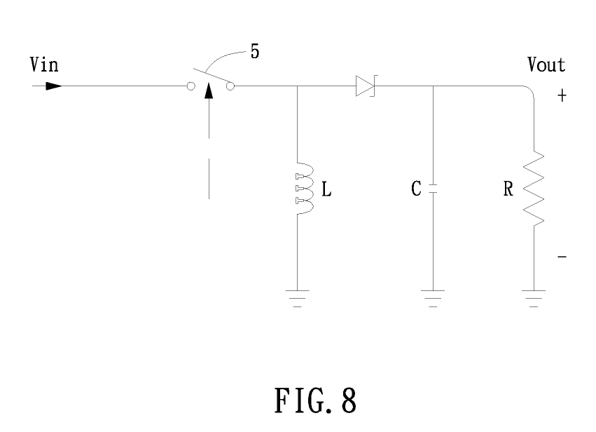

Please refer to FIG. 6, FIG. 7 and FIG. 8 for a buck circuit, a boost circuit and a buck-boost circuit, respectively. Each of these circuits comprises an inductor L, a capacitor C, a resistor R, a Zener diode D and a pulse-width modulation (PWM) or pulse-frequency modulation (PFM) switch 5. In FIG. 6, the input voltage Vin is boosted by the circuit to a higher output voltage Vout. In FIG. 7, the input voltage Vin is bucked by the circuit to a lower output voltage Vout. In FIG. 8, the input voltage Vin can be boosted by the circuit to a higher output voltage Vout or bucked by the circuit to a lower output voltage Vout. However, the configurations of the circuits in FIGS. 6 to 8 are conventional and detailed descriptions thereof are thus omitted.

Therefore, the disclosure of the present invention has advantages over the prior art that uses a plurality of small-current p-MOSFETs so that the p-MOSFETs are turned on in batches to limit the input current to flow into the load terminal. These advantages include:

1) less layout space for disposing the p-MOSFET inside an IC;

2) flexibility in disposing the p-MOSFET inside or outside an IC to achieve precisely control the DC-to-DC inverter without affecting the input voltage and provide a turn-on delay time for the p-MOSFET; and

3) better power management quality due to simplified digital-to-analog circuitry and less layout space.

Accordingly, the present invention discloses a digital-to-analog converting circuit for power soft-switching for controlling a p-channel metal-oxide-semiconductor field-effect transistor (p-MOSFET) so as to turn on the power. The digital-to-analog converting circuit is used to precisely control the turn-on resistance of the p-MOSFET so that the input current is controlled. Moreover, the digital control data of the digital-to-analog converting circuit is adjusted according to the regulating capacitance at the load terminal in order for use in various electronic products Therefore, the present invention has been examined to be new, non-obvious and useful.

Although this invention has been disclosed and illustrated with reference to particular embodiments, the principles involved are susceptible for use in numerous other embodiments that will be apparent to persons skilled in the art. This invention is, therefore, to be limited only as indicated by the scope of the appended claims.

What is claimed is:

1. A digital-to-analog converting circuit for power soft-switching, comprising:
a metal-oxide-semiconductor field-effect transistor (MOSFET);
a digital-to-analog control circuit, for controlling the MOSFET to operate in either the cut-off region, the saturation region or the linear region;
a digital control unit, using an output signal so as to control an input current into the MOSFET; and
a DC-to-DC inverter, controlled by the MOSFET so as to invert external DC power into a certain level for electronic products.

2. The digital-to-analog converting circuit for power soft-switching as recited in claim 1, wherein the MOSFET is a p-channel MOSFET.

3. The digital-to-analog converting circuit for power soft-switching as recited in claim 1, wherein the DC-to-DC inverter comprises a buck-boost circuit.

4. The digital-to-analog converting circuit for power soft-switching as recited in claim 1, wherein the DC-to-DC inverter comprises a boost circuit.

5. The digital-to-analog converting circuit for power soft-switching as recited in claim 1, wherein the DC-to-DC inverter comprises a buck circuit.

6. The digital-to-analog converting circuit for power soft-switching as recited in claim 1, further comprising a driver disposed between the digital-to-analog control circuit and the digital control unit.

7. The digital-to-analog converting circuit for power soft-switching as recited in claim 1, wherein the digital-to-analog control circuit comprises a plurality of resistors (R's and 2R's).

8. A digital-to-analog converting circuit for power soft-switching, comprising:
a p-channel metal-oxide-semiconductor field-effect transistor (p-MOSFET);
a digital-to-analog control circuit, for controlling the MOSFET to operate in either the cut-off region, the saturation region or the linear region;
a digital control unit, using an output signal so as to control an input current into the MOSFET; and
a DC-to-DC inverter comprises a buck-boost circuit, controlled by the MOSFET so as to invert external DC power into a certain level for electronic products.

9. A digital-to-analog converting circuit for power soft-switching, comprising:
a p-channel metal-oxide-semiconductor field-effect transistor (p-MOSFET);
a digital-to-analog control circuit, for controlling the MOSFET to operate in either the cut-off region, the saturation region or the linear region;
a digital control unit, using an output signal so as to control an input current into the MOSFET; and
a DC-to-DC inverter comprises a boost circuit, controlled by the MOSFET so as to invert external DC power into a certain level for electronic products.

10. A digital-to-analog converting circuit for power soft-switching, comprising:
a p-channel metal-oxide-semiconductor field-effect transistor (p-MOSFET);
a digital-to-analog control circuit, for controlling the MOSFET to operate in either the cut-off region, the saturation region or the linear region;
a digital control unit, using an output signal so as to control an input current into the MOSFET; and
a DC-to-DC inverter comprises a buck circuit, controlled by the MOSFET so as to invert external DC power into a certain level for electronic products.
